(19) United States
(12) Patent Application Publication
(10) Pub. No.: US 2022/0382668 A1
(43) Pub. Date: Dec. 1, 2022

(54) SYSTEMS AND METHODS FOR CONCURRENT AND AUTOMATED TESTING OF ZONED NAMESPACE SOLID STATE DRIVES

(71) Applicant: Advantest Corporation, Tokyo (JP)

(72) Inventors: Srdjan Malisic, San Jose, CA (US); Chi Yuan, San Jose, CA (US)

(21) Appl. No.: 17/333,729

(22) Filed: May 28, 2021

(51) Int. Cl. G06F 11/36

(52) U.S. Cl. CPC G06F 11/3688; G06F 11/3692

(57) ABSTRACT

Embodiments of the present invention provide systems and methods for automatically performing DUT testing on a large number of ZNS SSDs in parallel and in accordance with the configuration and restrictions associated with the various zones that comprise the address space of the ZNS SSDs. A computer process detects ZNS devices and their characteristics (e.g., zone parameters) and uses novel methods of executing read and write tests that can test unique features of ZNS devices. For example, some embodiments perform efficient and effective testing controls that account for numerous differences in ZNS characteristics and geometries between different device models. Embodiments can track the states of a large number of zones and handle each zone based on predetermined test specifications.

### FIELD

Embodiments of the present invention generally relate to the field of device testing. More specifically, embodiments of the present invention relate to methods and systems for testing zoned namespace solid state drives.

### BACKGROUND

A device or equipment under test (e.g., a DUT) is typically tested to determine the performance and consistency of the device before the device is sold. The device can be tested using a large variety of test cases, and the result of the test cases is compared to an expected output result. When the result of a test case does not match the expected output value, debugging is performed in an attempt to identify and correct any defects that result from the device and/or to bin the device based on performance.

A DUT is usually tested by automatic or automated test equipment (ATE), which may be used to conduct complex testing using software and automation to improve the efficiency of testing. The DUT may be a memory device or component that is intended to be integrated into a final product, such as a computer or other electronic device.

Solid state drives (SSDs) have become commonly used for large data centers and enterprise software applications. An SSD is a solid-state storage device that stores data persistently using flash memory. Recently, a new type of SSD has been introduced to improve performance and durability of SSDs by dividing the address space into distinct zones. These drives can be operated using an advanced Non Volatile Memory express (NVMe) command set and are known commercially as Zoned Namespaces (ZNS) SSDs. Conventional SSDs present the entire drive as sectors, and the system can write to any location and read from any location on the drive any time. In contrast, the zones of a ZNS SSD are configured using different operating parameters that restrict how the zones can be written (e.g., a limited number of sequential writes) or otherwise accessed (e.g., cleared). ZNS namespace is typically divided into a large number of zones of equal sizes. In one example, a 1 TB ZNS SSD can be segmented into a number of 2 GB zones, etc.

ZNS SSDs closely mirror the physical layout of the underlying flash storage which significantly simplifies the flash translation layer FTL in ZNS SSDs. This improvement can greatly reduce the amount of DRAM needed for ZNS SSDs, and reduces the costs of ZNS SSDs significantly. Unfortunately, existing NVMe testing methods cannot be used to test ZNS devices. These existing approaches are unable to account for the particular operating parameters of ZNS SSDs and cannot test these devices whatsoever.

### SUMMARY

Accordingly, embodiments of the present invention provide systems and methods for automatically performing DUT testing on a large number of ZNS SSDs in parallel and in accordance with the configuration and restrictions associated with the various zones that comprise the address space of the ZNS SSDs. Within the system, a computer process detects ZNS devices and their characteristics (e.g., device/zone parameters) and uses novel methods of executing read and write performance tests that can test unique features of ZNS devices. Embodiments of the present invention can track the states of a large number of zones and handle each zone based on predetermined test specifications, for instance.

According to one embodiment, a method of testing a zoned namespace solid state drive is disclosed. The method includes accessing zone parameters of a plurality of ZNS SSDs, executing testing programs to test the plurality of ZNS SSDs according to the zone parameters, and reporting test results of the testing programs.

According to some embodiments, the executing testing programs are performed by a processor (e.g., CPU) executing a Linux operating system, and further including sending API instructions to a field programmable gate array (FPGA) coupled to the ZNS SSDs to test the plurality of ZNS SSDs using the zone parameters according to the testing programs, for instance.

According to some embodiments, executing testing programs includes testing the ZNS SSDs in parallel.

According to some embodiments, the zone parameters include at least one of a number of zones in the ZNS SSDs, a zone size of the ZNS SSDs, a maximum number of open zones of the ZNS SSDs, a maximum zone capacity of the ZNS SSDs, and a minimum zone capacity of the ZNS SSDs.

According to some embodiments, the method includes receiving a-number of zones in the ZNS SSDs, a zone size of the ZNS SSDs, and a maximum number of open zones, from a ZNS DUT controller.

According to some embodiments, the method includes scanning all zones of the ZNS SSDs to determine zone capacity of the ZNS SSDs, and calculating a maximum zone capacity and a minimum zone capacity of the ZNS SSDs based on the zone capacity of the ZNS SSDs.

According to some embodiments, the ZNS SSDs can include zones with the same capacities.

According to some embodiments, executing testing programs includes performing write performance tests using a zone-based testing mode.

According to some embodiments, the executing testing programs includes performing read performance tests using a zone-based operating mode and a logical block address (LBA)-based operating mode.

According to a different embodiment, a system for stimulating a device under test (DUT) is disclosed. The system includes a processor executing a Linux-based operating system, and a memory in communication with the processor for storing data and instructions, where the processor performs a method of testing zoned namespace (ZNS) solid state drives (SSDs). The method includes accessing zone parameters of a plurality of ZNS SSDs, executing testing programs to test the plurality of ZNS SSDs according to the zone parameters, and reporting test results of the testing programs.

According to another embodiment, a method of testing a zoned namespace (ZNS) solid state drive (SSD) is disclosed. The method includes executing a plurality of testing programs to send API instructions to a first FPGA and to a second FPGA, the first FPGA performing testing operations on a first plurality of ZNS SSDs according to the API instructions, and the second FPGA performing testing operations on a second plurality of ZNS SSDs according to the API instructions.

According to some embodiments, the method includes accessing device information of the ZNS SSDs, where the first FPGA and second FPGA perform the testing operations according to the device information of the respective ZNS SSDs.

According to some embodiments, the first FPGA performs write performance tests on the first plurality of ZSN SSDs using a zone-based testing mode.

### BRIEF DESCRIPTION OF THE DRAWINGS

The accompanying drawings, which are incorporated in and form a part of this specification, illustrate embodiments of the invention and, together with the description, serve to explain the principles of the invention:

FIG. 1 is a block diagram of an exemplary ZNS SSD device logical block addressing range divided into zones according to embodiments of the present invention.

FIG. 2 is a block diagram depicting an exemplary tester FPGA for testing a large number of ZNS SSDs in parallel according to embodiments of the present invention.

FIG. 3 depicts an exemplary testing system for testing a large number of ZNS SSDs in parallel using multiple FPGAs according to embodiments of the present invention.

FIG. 4 depicts an exemplary test flow for testing ZNS SSDs according to embodiments of the present invention.

FIG. 5 depicts exemplary LBAs for writing data to zones of a ZNS SSD using a limited size area in front of the zone write pointer that permits limited non-sequential writes to ZNS device according to embodiments of the present invention.

FIG. 6 is a flow chart depicting an exemplary sequence of computer implemented steps of a computer controlled process for automatically testing ZNS SSDs according to embodiments of the present invention.

FIG. 7 is a block diagram and data flow diagram for automatically testing ZNS SSDs according to embodiments of the present invention.

FIG. 8 depicts an exemplary computer platform upon which embodiments of the present invention may be implemented.

### DETAILED DESCRIPTION

Reference will now be made in detail to several embodiments. While the subject matter will be described in conjunction with the alternative embodiments, it will be understood that they are not intended to limit the claimed subject matter to these embodiments. On the contrary, the claimed subject matter is intended to cover alternative, modifications, and equivalents, which may be included within the spirit and scope of the claimed subject matter as defined by the appended claims.

Furthermore, in the following detailed description, numerous specific details are set forth in order to provide a thorough understanding of the claimed subject matter. However, it will be recognized by one skilled in the art that embodiments may be practiced without these specific details or with equivalents thereof. In other instances, well-known methods, procedures, components, and circuits have not been described in detail as not to unnecessarily obscure aspects and features of the subject matter.

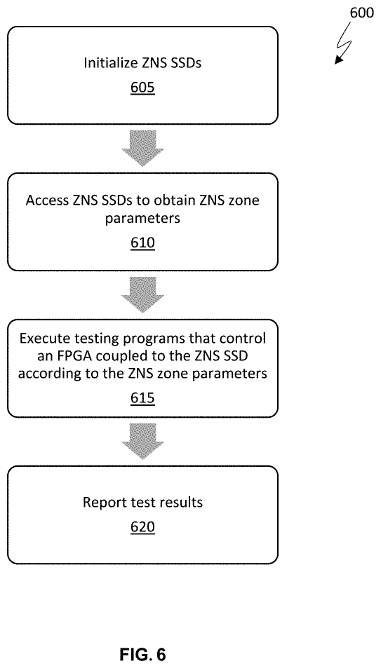

Portions of the detailed description that follows are presented and discussed in terms of a method. Although steps and sequencing thereof are disclosed in a figure herein (e.g., FIG. 6) describing the operations of this method, such steps and sequencing are exemplary. Embodiments are well suited to performing various other steps or variations of the steps recited in the flowchart of the figure herein, and in a sequence other than that depicted and described herein.

Some portions of the detailed description are presented in terms of procedures, steps, logic blocks, processing, and other symbolic representations of operations on data bits that can be performed on computer memory. These descriptions and representations are the means used by those skilled in the data processing arts to most effectively convey the substance of their work to others skilled in the art. A procedure, computer-executed step, logic block, process, etc., is here, and generally, conceived to be a self-consistent sequence of steps or instructions leading to a desired result. The steps are those requiring physical manipulations of physical quantities. Usually, though not necessarily, these quantities take the form of electrical or magnetic signals capable of being stored, transferred, combined, compared, and otherwise manipulated in a computer system. It has proven convenient at times, principally for reasons of common usage, to refer to these signals as bits, values, elements, symbols, characters, terms, numbers, or the like.

It should be borne in mind, however, that all of these and similar terms are to be associated with the appropriate physical quantities and are merely convenient labels applied to these quantities. Unless specifically stated otherwise as apparent from the following discussions, it is appreciated that throughout, discussions utilizing terms such as “accessing,” “writing,” “including,” “storing,” “transmitting,” “associating,” “identifying,” “encoding,” or the like, refer to the action and processes of a computer system, or similar electronic computing device, that manipulates and transforms data represented as physical (electronic) quantities within the computer system's registers and memories into other data similarly represented as physical quantities within the computer system memories or registers or other such information storage, transmission or display devices.

### Concurrent and Automated Testing of Zoned Namespace Solid State Drives

Embodiments of the present invention provide systems and methods for automatically performing DUT testing on a large number of ZNS SSDs in parallel and in accordance with the configuration and restrictions associated with the various zones that comprise the address space of the ZNS SSDs. Within the system, a computer process detects ZNS devices and their characteristics (e.g., zone parameters) and uses novel methods of executing read and write tests that can test unique features of ZNS devices. For example, some embodiments perform efficient and effective testing controls that account for numerous differences in ZNS characteristics and geometries between different device models. Embodiments can track the states of a large number of zones and handle each zone based on predetermined test specifications.

The total number of zones can be hundreds of thousands for each ZNS device, and millions of zones per tester. The high throughput of the testing device advantageously reduces the overall time and cost required for testing, and also enables the testing device to more closely approximate actual conditions (e.g., large data centers)

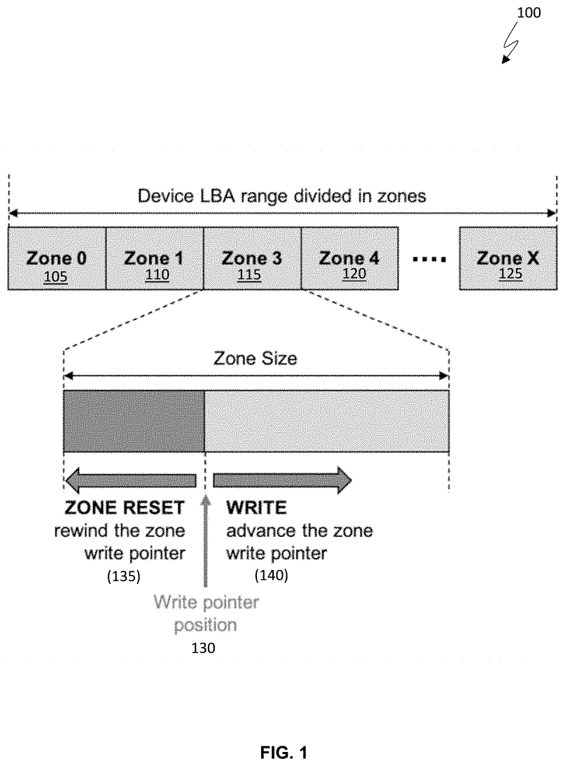

With regard to FIG. 1, an exemplary ZNS SSD device logical block addressing range 100 that is divided into zones is depicted according to embodiments of the present invention. As depicted in FIG. 1, the exemplary ZNS SSD device logical block addressing range can include any Xnumber of zones (e.g., zones 105, 110, 115, 120, 125). Some ZNS SSD devices can be configured to divide the logical block addressing range 100 into up to hundreds of thousands of individual zones, and over 4000 zones can be written to at any time in one implementation. Testing a device having an extremely high number of zones requires coordination and accommodation of the constraints and parameters of the ZNS device.

In the example of FIG. 1, the zones of the address space are of equal size (“zone size”), and each zone has a capacity (“zone capacity”) that is less than the zone size. Each zone is generally written sequentially from the zone start logical block address (LBA) (up to zone capacity), and random writes to zones are not supported. However, according to some embodiments, random writes within a limited area of a zone can be allowed.

The number of zones that can be concurrently written to (“maximum open resources”) in a ZNS SSD is generally limited to a specific number. The maximum open resources value (or “threshold”) is advertised in the drive's namespace identify data structure. In most cases writing in a zone can only be performed sequentially to a write position tracked by write pointer 130. A zone reset operation 135 can be performed to rewind the zone position pointer, and a write operation 140 can be used to write data and advance the zone write position.

Some of ZNS devices have limited size area in front of write pointer of each zone, and this area can be written sequentially or randomly with queued multiple commands. This area is known as ZRWA (zone random write area). Typical size of ZRWA can be few MB.

Reading from zones of a ZNS SSD is much less constrained as zones can be read sequentially or randomly. Read IOs can originate from any address and any zone as long as the read IOs are between the start of the zone (“zone start”) and zone capacity. The number of zones that can be read concurrently is not limited. Importantly, the gap between zone capacity and the next zone start cannot be accessed by read or write operations.

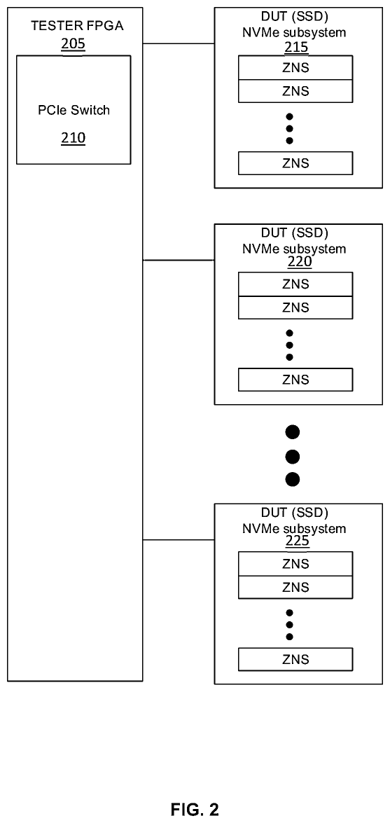

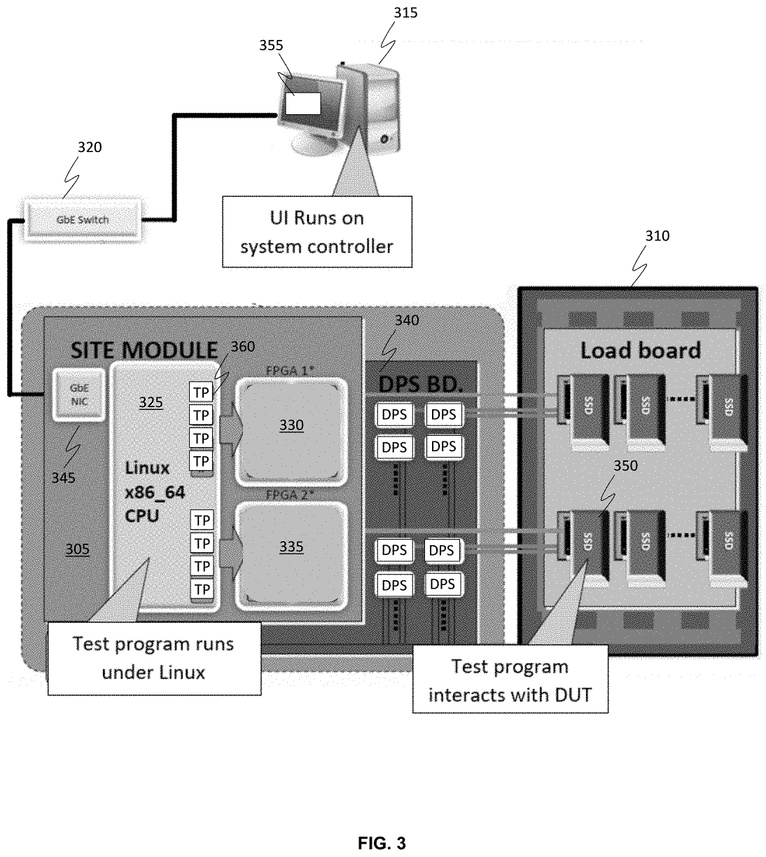

FIG. 2 depicts an exemplary tester field programmable gate array (FPGA) 205 for testing a large number of ZNS SSDs in parallel according to embodiments of the present invention. In the example of FIG. 2, tester FPGA 205 includes a PCIe Switch 210 coupled to a plurality of ZNS SSDs. PCIe switch is conduit for ZNS NVMe commands and APIs originating in CPU (325 in FIG. 3) and targeting ZNS SSDs 215, 220, and 225. ZNS SSDs 215, 220, and 225 host NVMe subsystems for storing and accessing data from the ZNS zones.

Tester software running on CPU 325 in (see FIG. 3) detects the coupled ZNS SSDs 215, 220, and 225 and the respective device characteristics (e.g., zone parameters), and performs write and read tests that exercise unique features of the coupled devices. Tester software running on CPU 325 tracks states of large number of ZNS zones, and handles each zone based on test specification. This can include querying each ZNS SSD to obtain device parameters, including zone parameters. In some cases, the number of zones is hundreds of thousands for each ZNS SSD, and the tester software running on CPU 325 can test millions of zones in total.

FIG. 3 depicts an exemplary testing system 300 for testing a large number of ZNS SSDs in parallel using multiple FPGAs according to embodiments of the present invention. In the example of FIG. 3, site module 305 includes a processor 325 executing a Linux operating system. Processor 325 can be a 64-bit x86 CPU, for example. Device power supply (DPS) board 340 includes several DPSs for supplying the voltage required to operate and test the DUTs. Site module 305 also includes a network interface (NIC) 345, such as a gigabit ethernet NIC, that communicates with a system controller 315 over network switch 320. The system controller 315 can be a computer system executing a testing system control user interface (UI), for example. The results of the testing by site module 305 can be reported to system controller 315 and displayed on graphical user interface (GUI) 355. The results of the performance tests can include the total number of zones processed, the number of times a zone is accessed, the distribution of zone access (e.g., in space/time), and the sequence in which the zones are accessed, for example.

Load board 310 includes multiple ZNS SSDs 350 for testing. Load board 310 receives commands from test programs 360 and receives voltage from DPS board 340. The commands include NVMe commands and commands of APIs configured for testing ZNS storage devices. Load board 310 can advantageously execute performance tests on large number of zones of ZNS SSDs 350 in parallel at high speeds, which enables faster and more efficient testing.

Test programs (“TPs”) 360 are executed by the Linux operating system using processor 325 to send instructions to FPGAs 330 and 335 for controlling the DUTs (ZNS SSDs). A software control layer handles constraints and geometries specific to the particular ZNS SSD being tested. The test programs interact with the DUTs to perform tests that can include read operations, write operations, zone clear operations, or management operations, for example. A test program can use multiple performance threads to perform the desired read and write combinations.

An API call (e.g., aai_nvme_dut_param_get) can be issued to query ZNS-specific DUT parameters, including the number of zones in the ZNS SSD, the zone size in LBAs, the maximum number of open zones, and the maximum and minimum zone capacity in LBAs. The number of zones in the ZNS SSD, the zone size in LBAs, and the maximum (“threshold”) number of open zones is advertised by the ZNS DUT controller unsolicited. Maximum and minimum zone capacity are calculated by the system controller after scanning the capacities of all zones. If all zones have the same capacity (which is presently the most common case), minimum and maximum capacities are equal.

After the DUT parameters are read, the test programs can use the following exemplary API commands:
aai_nvme_zone display( )—to display all zones or only zones that meet certain criteria.
aai_nvme_zone_info_update( )—to issue zone management command receive action ‘Report Zones’ and update system process information about zones.
aai_nvme_zone_mgmt_recv( )—to issue zone management command receive and get report with list of zone descriptors.
aai_nvme_zone_mgmt_send( )—to issue zone management command open/close/finish/reset on one zone or all zones.

Different ZNS perf test operation modes are supported according to embodiments of the present invention. According to some embodiments, write performance tests are always performed using a zone-based testing mode, and read performance tests can be performed using either a zone-based or LBA-based operating mode.

In a LBA-based ZNS performance test, IOs are sent in the same way as in a conventional namespace. As a further restriction, only valid areas of zones of the ZNS can be accessed (e.g., the area between zone start and the zone capacity).

Zone-based ZNS performance tests send IOs concurrently to a number of zones. The ZNS zone is the unit of operation, and the next zone is selected only when one of the currently processed zones is complete. The next zone is selected either sequentially (e.g., if random addressing is 0) or randomly (e.g., if random addressing is 100%). Zones can be selected either by specifying start and end LBAs, or by specifying a specific list of zones.

For write operations, each zone is limited to one outstanding write operation at a time (queue size per zone=1). However, the queue size for performance testing results in submitting write IOs to multiple zones concurrently (up to the limit advertised by controller).

One outstanding write per zone limitation does not apply to zones that support ZRWA and that are opened with ZRWA option enabled. For verification purposes, zone-based reads are performed in the same manner and with similar constraints. By default, for zone writes, the test program can issue a zone reset command at the beginning of a zone write and can issue a zone finish command at the end of the zone write.

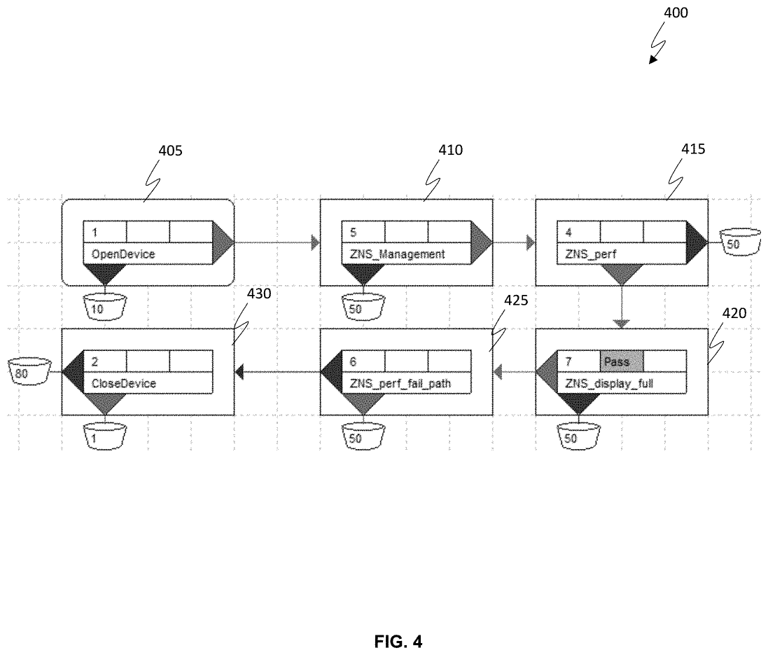

FIG. 4 depicts an exemplary test flow 400 for testing ZNS SSDs according to embodiments of the present invention.

At step 405, a DUT (ZNS SSD) is powered on or otherwise initialized for communicating with the testing system. Step 405 includes scanning and identifying all namespaces and accessing a list of DUT zone descriptors. Each zone descriptor includes a zone start LBA, zone capacity, zone attributes, zone state, and zone write pointer. The test program has no limit on the number of namespaces and number of zones per namespace.

At step 410, a ZNS management operation is performed to display a list of all zones, zone states, zone attributes, open zones, and reset zones on a GUI executed by a control system.

At step 415 multiple ZNS performance tests are performed on the DUT, where ZNS performance tests are expected to be passed by the DUT. The results of the performance tests can be reported to the control system and displayed on the GUI. The results of the performance tests can include the total number of zones processed, the number of times a zone is accessed, the distribution of zone access (e.g., in space/time), and the sequence in which the zones are accessed.

At step 420, a list of all full zones is displayed on-screen on the GUI of the control system.

At step 425, multiple ZNS performance tests are performed on the DUT, where the ZNS performance tests are expected to fail.

At step 430, the DUT is closed.

In both test segments (step 415 and 425), a test method executes, for example, three performance tests concurrently using three threads:
Thread 0 executes a read/write performance test on conventional namespace 1.
Thread 1 executes a 100% write performance test on ZNS namespace 2.
Thread 2 executes a 100% read performance test on zoned ZNS namespace 2.

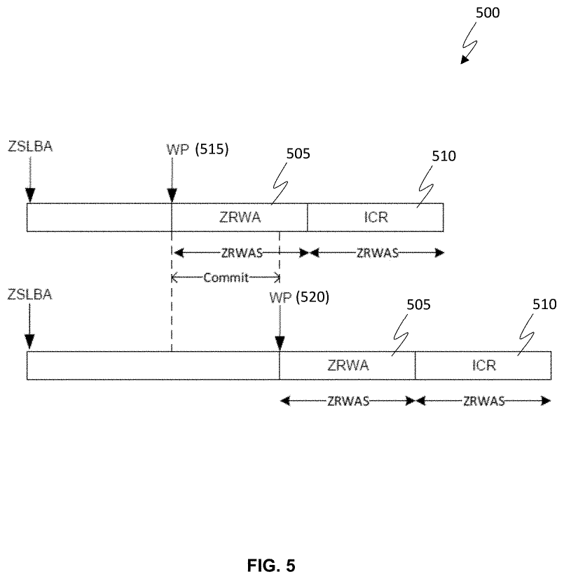

FIG. 5 depicts exemplary LBAs for writing data to zones of a ZNS SSD using a limited size area (“ZRWA”) in front of zone write pointer (WP) 515 that permits limited non-sequential writes to ZNS device according to embodiments of the present invention. ZRWA 505 is allocated to a zone when the zone is opened. The number of ZRWAs 505 per device is advertised in the controller identify structure as MRWZ (Maximum Random Write Zones).

IOs written to ZRWA 505 (between WP and WP+ZRWAS) are not immediately committed to drive flash. Moreover, these IOs do not trigger immediate WP change. IOs can be committed in two different ways to the drive and move the WP:
1. Explicit commit commands use Zone Management Send commands with a “Commit Zone” action.
2. Implicit commits occur any time a write is submitted in implicit commit region (ICR) 510. ICR 510 can be defined as the region (WP+ZRWAS, WP+2*ZRWAS). ZRWAS is ZRWA size. Writing in the implicit commit area will move WP 515 so that the distance between the most recent write in the implicit commit area and new WP 520 equals ZRWA.

Table I below lists an exemplary set of APIs and values for ZNS performance testing of ZNS SSDs according to embodiments of the present invention. The API instructions can be executed by the CPU, then sent to an FPGA, which is coupled to a load board including a large number of ZNS SSDs to automatically test the ZNS SSDs in parallel.

```
TABLE I
VastCtrl enum values for ZNS perf tests:
/* Number of zones to process per loop */
eVAST_CTRL_NUM_ZONES_REQUESTED = 29,
/* ZNS-specific options */
eVAST_CTRL_ZONE_OPTIONS = 30,
/* Zone list pointer */
eVAST_CTRL_ZONE_LIST_PTR = 31,
/* Zone list length */
eVAST_CTRL_ZONE_LIST_LEN = 32,
/* Number of zones to r/w concurrently in zone-based access
mode */
eVAST_CTRL_NUM_CONCURRENT_ZONES = 34,
/* Max LBAs to read or write in a zone */
// Reserved 35,
/* Number of IOs per ZRWA */
eVAST_CTRL_ZRWA_NUM_IO = 36,
/* Percentage of random IOs in ZRWA */
eVAST_CTRL_ZRWA_RANDOM_PERCENT = 37,
/* Seed for random IOs in ZRWA */
eVAST_CTRL_ZRWA_RANDOM_SEED = 38,
/* Zone overwrite and over-read limit, as % of zone
capacity */
/* Valid values: 0 (no limit) and 1-99 (limit) */
eVAST_CTRL_ZONE_OVERWRITE_PERCENT_LIMIT = 39,
enum VastCtrlZnsOption:
typedef enum
{
VczoResetZoneBeforeWritting = (1 << 0),
VczoFinishFullyWrittenZone = (1 << 1),
VczoLbaBasedAccess = (1 << 4),
VczoUseZrwa = (1 << 5),
VczoDefault = (VczoResetZoneBeforeWritting |
VczoFinishFullyWrittenZone),
// for backwards compatibility
VczoZoneRandomWriteAreaEn = VczoUseZrwa,
} VastCtrlZnsOption;
eVastPerfResults enum values for ZNS perf test results:
NVMe ZNS SW PDD
// ZNS handling
eVAST_PERF_READ_TOTAL_ZONES,
eVAST_PERF_WRITE_TOTAL_ZONES,
eVAST_PERF_TOTAL_ZONES,
} eVastPerfResults;
APIs for NVMe ZNS handling:
enum AaiNvmeDp
{
  AaiNvmeDpNumZones = 100,
  AaiNvmeDpZoneSizeLbas = 101,
  AaiNvmeDpMaxZoneCapaci = 102,
  tyLbas
  AaiNvmeDpMinZoneCapaci = 103,
  tyLbas
  AaiNvmeDpMaxOpenZones = 104,
  AaiNvmeDpZrwaSize = 105, // ZRWA size
  AaiNvmeDpEnforcedWdgaL = 106, // Enforced Write Data Granularity
  bas and Alignment,
in LBAs
AaiNvmeDpZoneDescExtSizeBytes = 107, // Report Zone
Descriptor extended size, in Bytes
};
/**
// for backwards compatibility AaiNvmeDpRandomWriteAreaSize
= AaiNvmeDpZrwaSize,
@param nsid Namespace ID.
@param param DUT paramter, one of AaiNvmeDp enums.
@return value for the specified DUT parameter (0 or
positive number) on success,
−1 on failure.
*/
int64_t aai_nvme_dut_param_get(uint32_t nsid, enum
AaiNvmeDp param);
enum AaiNvmeZoneMgmtSendOpt
{
AaiNzmsDefault = 0,
AaiNzmsSelectAll = 1 << 8, AaiNzmsZrwaAllocation = 1 <<
9, // ZRWA Allocation
// for backwards compatibility AaiNvmeZoneMgmtDefault
= AaiNzmsDefault, AaiNvmeZoneMgmtSelectAll =
AaiNzmsSelectAll,
AaiNvmeZoneMgmtZrwaAllocation = AaiNzmsZrwaAllocation,
AaiNzmsZRWAA  = AaiNzmsZrwaAllocation,
;
VastStatus aai_nvme_zone_mgmt_send(uint8_t send_action,
uint64_t start_lba,
uint32_t zone_send_options,
void *descriptor_buf,
uint32_t descriptor_buf_size);
VastStatus aai_nvme_zone_mgmt_recv(enum
nvme_zone_recv_action recv_action,
uint64_t start_lba,
enum nvme_zone_report_type recv_action_specific_field,
uint8_t partial_report,
void *buf,
uint32_t buf_size);
int32_t aai_nvme_zone_display(uint64_t start_lba, uint32_t
max_zones, uint8_t zone_state, bool update_info);
VastStatus aai_nvme_zone_info_update(void);
enum NVMeZonePerfResultType
{
NVMeZoneFreqencyCount = 1, // One entry for each zone,
entries[0] is how many
// time, zone 0 is accessed.
// If DUT has N zones, first N entries are valid.
// Currently, frequencis for the first 80000 zones
// are stored. Reset to default entry value 0 at
// the start of perf test.
NVMeZoneAccessSequence = 2, // entries[0] is the first zone
tested, entries[1]
// is the second one. Currently up to frist 80000
// entries are stored. Reset to default value −1
// at the start of perf test.
} ;
int aai_nvme_zone_perf_result_get(int threadIndex, enum
NVMeZonePerfResultType type, uint32_t * entries, uint32_t
entry_count);
int aai_nvme_identify(uint32_t nsid, uint32_t cdw10,
uint32_t cdw11, uint32_t cdw14, uint32_t timeout_{——}ms, void
*data, size_t data_len) ;
```

With regard to FIG. 6, an exemplary sequence of computer implemented steps of a process 600 for automatically testing a ZNS SSD is depicted according to embodiments of the present invention. The computer implemented steps 600 may be performed using a Linux-based operating system executing test programs that issue commands to multiple ZNS SSDs to perform testing operations according to embodiments of the present invention. Of course any number of commercially available computer systems can be used as a platform for processes 600. The testing operations can be performed according to NVMe ZNS commands and custom API commands described herein. Executing multiple test programs in parallel for a large number of ZNS SSDs enhances the speed and robustness of the testing environment.

At step 605, multiple ZNS SSDs are powered and initialized for communication with the testing system.

At step 610, the ZNS SSDs are accessed by the testing system to obtain ZNS zone parameters. Step 605 can include issuing API instructions that query the device for the ZNS zone parameters. Some ZNS zone parameters can be advertised by the ZNS SSDs. According to some embodiments, step 610 includes issuing API instructions to control the location of a write pointer or allocate a ZRWA for modification of previously written data using a write queue. Data from the write queue can be written using explicit and/or implicit commit commands.

At step 615, one or more test programs are executed by the testing system to test the ZNS SSDs. The test programs are executed by a processor (e.g., a CPU) of a site module. The CPU typically is a 64-bit CPU hosting a Linux OS. The test program is configured to test the ZNS SSDs according to the parameters and geometry of the ZNS SSDs. By testing a large number of ZNS SSDs in parallel, the speed and quality of the testing is improved as more devices can be tested at a given time and the testing conditions more closely resemble real world use cases (e.g., data centers). The testing programs can include performance tests that are designed to be passed by the DUT, and performance tests that are designed to be failed by the DUT.

At step 620, the results of the test are reported by the testing system. For example, the test results can be reported to a control system and displayed on a graphical user interface rendered by the control system.

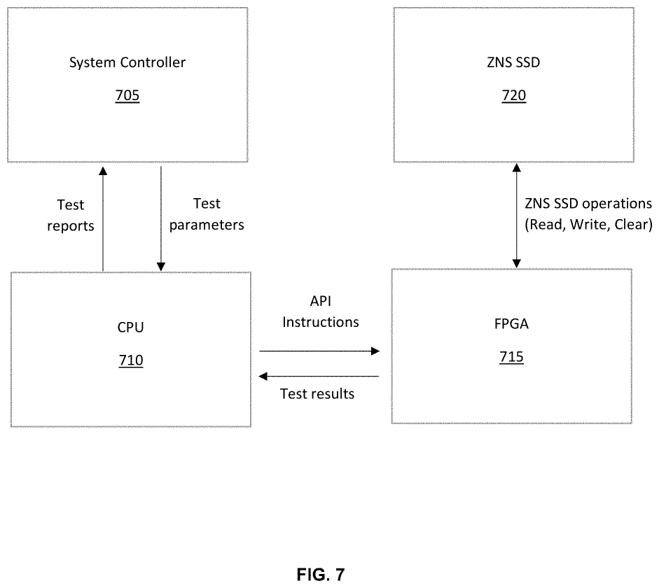

With regard to FIG. 7, a block diagram and data flow diagram 700 for automatically testing a ZNS SSD is depicted according to embodiments of the present invention. System controller 705 is a computer system executing a graphical user interface used to display reported test results and manually control test program parameters. System controller 705 communicates with CPU 710 of site module 730 over a computer network, such as gigabit ethernet.

Processor (e.g., CPU) 710 executes a Linux-based operating system that sends API instructions to devices through FPGA 715. The instructions can include NVMe commands and API instructions specifically designed for ZNS SSDs (see, Table I).

FPGA 715 performs testing operations on ZNS SSD 720 defined by a test program running on the Linux OS executing on CPU 710. The test results are accessed by CPU 710 and used to generate test reports. The test reports can be sent to system controller 705 for storage and/or display on-screen on a graphical user interface.

### Exemplary Test System

Embodiments of the present invention are drawn to electronic systems for performing DUT testing on ZNS SSDs. A large number of ZNS SSDs can be tested concurrently using custom APIs. The following discussion describes one such exemplary electronic system or computer system that can be used as a platform for implementing embodiments of the present invention.

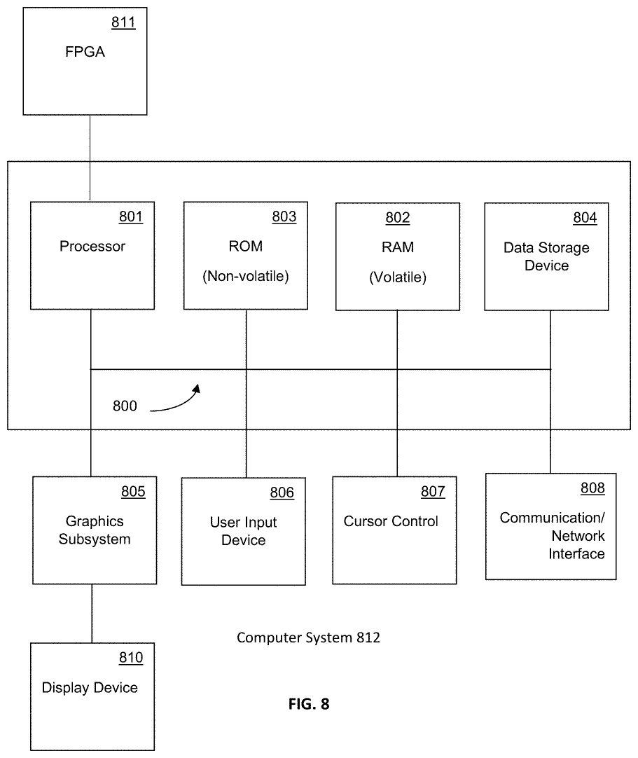

In the example of FIG. 8, the exemplary computer system 812 (e.g., an agent system or supervisor system) includes a central processing unit (CPU) 801 for running software applications and an operating system (e.g., a Linux or a Linux-based operating system). The CPU sends API instructions and NVMe commands to multiple DUTs through one or more FPGAs 811. FPGA 811 is coupled to a plurality of ZNS SSDs for testing using ZNS SSD operations (e.g., read, write, and management operations). Random access memory 802 and read-only memory 803 store applications and data for use by the CPU 801. Data storage device 804 provides non-volatile storage for applications and data and may include HDs or SSDs.

A communication or network interface 808 allows the computer system 812 to communicate with other computer systems, devices, networks, or devices via an electronic communications network. The optional display device 810 may be any device capable of displaying visual information in response to a signal from the computer system 812 and may include a flat panel touch sensitive display, for example. The components of the computer system 812, including the CPU 801, memory 802/803, data storage 804, user input devices 806, and graphics subsystem 805 may be coupled via one or more data buses 800.

In the embodiment of FIG. 8, an optional graphics sub-system 805 may be coupled with the data bus and the components of the computer system 812. Graphics sub-system 805 outputs display data to optional display device 810. The display device 810 may be communicatively coupled to the graphics subsystem 805 using HDMI, DVI, DisplayPort, VGA, etc. Graphics sub-system 805 can display testing reports on display device 810.

Some embodiments may be described in the general context of computer-executable instructions, such as program modules, executed by one or more computers or other devices. Generally, program modules include routines, programs, objects, components, data structures, etc. that perform particular tasks or implement particular abstract data types. Typically the functionality of the program modules may be combined or distributed as desired in various embodiments.

Embodiments of the present invention are thus described. While the present invention has been described in particular embodiments, it should be appreciated that the present invention should not be construed as limited by such embodiments, but rather construed according to the following claims.

What is claimed is:

1. A method of testing zoned namespace (ZNS) solid state drives (SSDs), the method comprising:
accessing zone parameters of a plurality of ZNS SSDs under test;
executing testing programs to test the plurality of ZNS SSDs according to the zone parameters; and
reporting test results of the testing programs.

2. The method as described in claim 1, wherein the executing testing programs is performed by a processor executing a Linux operating system, and further comprising the processor sending API instructions to the plurality of ZNS SSDs through an FPGA to test the plurality of ZNS SSDs using the zone parameters according to the testing programs.

3. The method as described in claim 1, wherein executing testing programs comprises testing the plurality of ZNS SSDs in parallel.

4. The method as described in claim 1, wherein the zone parameters comprise at least one of: a number of zones in the plurality of ZNS SSDs; a zone size of the ZNS SSDs; a maximum number of open zones of the ZNS SSDs; a maximum zone capacity of the ZNS SSDs; and a minimum zone capacity of the ZNS SSDs.

5. The method as described in claim 1, further comprising receiving at least one of: a number of zones in the plurality of ZNS SSDs; a zone size of the plurality of ZNS SSDs; and a maximum number of open zones, from a DUT controller.

6. The method as described in claim 1, further comprising:
scanning all zones of the plurality of ZNS SSDs to determine zone capacity of the ZNS SSDs; and
calculating a maximum zone capacity and a minimum zone capacity of the ZNS SSDs based on the zone capacity of the plurality of ZNS SSDs.

7. The method as described in claim 1, wherein the zones of the ZNS SSDs comprise equal zone capacities.

8. The method as described in claim 1, wherein the executing testing programs comprises performing write performance tests using a zone-based testing mode.

9. The method as described in claim 1, wherein the executing testing programs comprises:
performing read performance tests using a zone-based operating mode; and
performing read performance tests using a logical block address (LBA) operating mode.

10. A system for simulating a device under test, the system comprising:
a processor executing a Linux-based operating system; and
a memory in communication with the processor for storing data and instructions, wherein the processor executes instructions to perform a method of testing zoned namespace (ZNS) solid state drives (SSDs), the method comprising:
accessing zone parameters of a plurality of ZNS SSDs;
executing testing programs to test the plurality of ZNS SSDs according to the zone parameters; and
reporting test results of the testing programs.

11. The system as described in claim 10, further comprising an FPGA in communication with the processor and the plurality of ZNS SSDs, and wherein the method further comprises sending API instructions to the FPGA to test the plurality of ZNS SSDs using the zone parameters according to the testing programs.

12. The system as described in claim 10, wherein the executing testing programs comprises testing the plurality of ZNS SSDs in parallel.

13. The system as described in claim 10, wherein the zone parameters comprise at least one of: a number of zones in the plurality of ZNS SSDs; a zone size of the plurality of ZNS SSDs; a maximum number of open zones of the plurality of ZNS SSDs; a maximum zone capacity of the plurality of ZNS SSDs; and a minimum zone capacity of the plurality of ZNS SSDs.

14. The system as described in claim 10, further comprising receiving at least one of: a number of zones in the plurality of ZNS SSDs; a zone size of the plurality of ZNS SSDs; and a maximum number of open zones, from a ZNS DUT controller.

15. The system as described in claim 10, wherein the method further comprises:
scanning zones of the plurality of ZNS SSDs to determine zone capacity of the ZNS SSDs; and
calculating a maximum zone capacity and a minimum zone capacity of the plurality of ZNS SSDs based on the zone capacity of the plurality of ZNS SSDs.

16. The system as described in claim 10, wherein the executing testing programs comprises:
performing read performance tests using a zone-based operating mode; and
performing read performance tests using a logical block address (LBA)-based operating mode.

17. The system as described in claim 10, wherein the executing testing programs comprises:
executing a first set of tests configured to be passed by the plurality of ZNS SSDs; and
executing a second set of tests configured to be failed by the plurality of ZNS SSDs.

18. A method of testing a zoned namespace (ZNS) solid state drive (SSD), the method comprising:
executing testing programs to perform zone-based testing on the ZNS SSD according to zone parameters of the ZNS SSD, wherein the ZNS SSD comprises a plurality of zones; and
collecting results of the testing programs, wherein the results comprise:
a sequence in which the plurality of zones of the ZNS SSD are accessed by the test program; and
a number of times the plurality of zones are accessed by the test program.

19. The method of claim 18, wherein the results of the test programs are stored in a table.

20. The method of claim 18, wherein the executing testing programs comprises:
executing a first set of tests configured to be passed by the ZNS SSD; and
executing a second set of tests configured to be failed by the ZNS SSD.
